(19) United States
(12) Patent Application Publication
(10) Pub. No.: US 2024/0106116 A1
(43) Pub. Date: Mar. 28, 2024

(54) WIDEBAND COMPACT RADIO FREQUENCY PHASE SHIFTER

(71) Applicant: Apple Inc., Cupertino, CA (US)

(72) Inventors: Morteza Tavakoli Taba, Ann Arbor, MI (US); Xiang Guan, Santa Clara, CA (US)

(21) Appl. No.: 18/105,610

(22) Filed: Feb. 3, 2023

Related U.S. Application Data
(60) Provisional application No. 63/409,320, filed on Sep. 23, 2022.

(51) Int. Cl. H01Q 3/36; H03H 7/18

(52) U.S. Cl. CPC H01Q 3/36; H03H 7/18

(57) ABSTRACT

A hybrid switched-type phase shifter (STPS) may include the π-type phase shifters and T-type phase shifters to provide more stable output signals over a wide frequency range. The hybrid STPS may provide output signals based on shifting a phase of the input signal having different frequencies across the frequency range by different phase shifts with relatively similar phase drifts resulting in a reduced phase error during operation. In some cases, the phase shifters discussed above may also include a number of capacitors and/or inductors. In some embodiments, a circuitry or layout of the phase shifters may be shared to reduce a total number of capacitors and therefore reduce a circuit area of the hybrid STPS. Moreover, stacking at least two inductors of the hybrid STPS may also reduce a circuit area for shifting the phase of the input signal by the desired phase shifts across the frequency range.

### CROSS-REFERENCE TO RELATED APPLICATIONS

This application claims priority to U.S. Provisional Application No. 63/409,320, filed Sep. 23, 2022, entitled “WIDEBAND COMPACT RADIO FREQUENCY PHASE SHIFTER,” the disclosure of which is incorporated by reference in its entirety for all purposes.

### BACKGROUND

The present disclosure relates generally to wireless communication, and more specifically to shifting phases in wireless signals.

In a wireless communication device, shifting (e.g., increasing or decreasing) a phase of a signal may facilitate wireless communication. A switched-type phase shifter may offer advantages such as a small size and increased control. However, the switched-type phase shifter may exhibit excessive phase error.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, phase shifting circuitry comprising a first phase shifter. The first phase shifter comprises a first inductor, a first capacitor coupled to a first terminal of the first inductor, and a second capacitor coupled to a second terminal of the first inductor. The first capacitor and the second capacitor are coupled to a first switch, and the first switch is coupled to a ground connection. The phase shifting circuitry also comprises a second phase shifter that comprises a third phase shifter. The third phase shifter comprises a second inductor, a third capacitor coupled to a second switch, and a fourth capacitor coupled to the second switch. The second switch is coupled to a third terminal of the second inductor, and a fourth terminal of the second inductor is coupled to the ground connection. The second phase shifter also comprises a third inductor, a fifth capacitor coupled to a third switch, and a sixth capacitor coupled to the third switch. The third switch is coupled to a fifth terminal of the third inductor, and a sixth terminal of the third inductor is coupled to the ground connection.

In another embodiment, an electronic device comprising one or more antennas and a hybrid switched-type phase shifter coupled to the one or more antennas. The hybrid switched-type phase shifter comprises a π-type phase shifter configured to shift a phase of an input signal by a first phase shift value, the input signal being transmitted by the one or more antennas or received by the one or more antennas. The hybrid switched-type phase shifter also comprises a first T-type phase shifter configured to shift the phase of the input signal by a second phase shift value, and a second T-type phase shifter configured to shift the phase of the input signal by a third phase shift value.

In yet another embodiment, a hybrid switched-type phase shifter comprising a π-type phase shifter coupled to an input port via a first set of switches, a first T-type phase shifter coupled to the input port via a second set of switches, and a second T-type phase shifter coupled to an output port. The second T-type phase shifter is coupled in series to the π-type phase shifter and the first T-type phase shifter.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a circuit diagram of a low-pass π-type phase shifter for shifting a phase of input signals, according to embodiments of the present disclosure;

FIG. 6 is a circuit diagram of a high-pass T-type phase shifter for shifting the phase of the input signals, according to embodiments of the present disclosure;

FIG. 7 is a circuit diagram of a first hybrid switched-type phase shifter (STPS) circuitry of the transmitter of FIG. 3, the receiver of FIG. 4, or both, according to embodiments of the present disclosure;

FIG. 8 is a circuit diagram of a second hybrid STPS circuitry of the transmitter of FIG. 3, the receiver of FIG. 4, or both, according to embodiments of the present disclosure;

FIG. 9 is a circuit diagram of the hybrid STPS circuitry of FIG. 8, according to embodiments of the present disclosure; and

FIG. 10 is an example layout of the inductors of the hybrid STPS circuitry of FIGS. 8 and 9, according to embodiments of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member, but the set may also include a set of multiple members.

This disclosure is directed to switched-type phase shifter (STPS) circuitry with reduced phase error. In particular, this disclosure is directed to hybrid STPS circuitry including π-type phase shifter and T-type phase shifters. As noted above, STPS circuitry may offer advantages such as a small size and increased control. This disclosure describes various embodiments of the hybrid STPS circuitry having an improved frequency range, reduced phase error across the frequency range, and/or smaller circuit area, among other advantages.

The hybrid STPS circuitry may include a π-type phase shifter (e.g., a low-pass phase shifter), a first T-type phase shifter (e.g., a high-pass phase shifter), and a second T-type phase shifter (e.g., a high-pass phase shifter). The π-type phase shifter, the first T-type phase shifter, and the second T-type phase shifter may each shift (e.g., positively shift, negatively shift) a phase of an input signal by a respective phase value. In some embodiments, the π-type phase shifter and the first T-type phase shifter may shift the phase of the input signal by 45° and the second T-type phase shifter may shift the phase of the input signal by −90°. In alternative or additional embodiments, the π-type phase shifter may shift the phase of the input signal by 45° and the first T-type phase shifter and the second T-type phase shifter may shift the phase of the input signal by +45°.

The hybrid STPS circuitry may also include a number of switches to couple and uncouple the π-type phase shifter, the first T-type phase shifter, and the second T-type phase shifter to an input terminal and an output terminal of the hybrid STPS circuitry. For example, a controller may provide control signals to couple and uncouple the π-type phase shifter, the first T-type phase shifter, and/or the second T-type phase shifter between the input terminal and the output terminal of the hybrid STPS circuitry. As such, the hybrid STPS circuitry may shift a phase of the input signals utilizing the π-type phase shifter, the first T-type phase shifter, and/or the second T-type phase shifter. Accordingly, the hybrid STPS circuitry may provide output signals by shifting a phase of the input signals based on a phase shift value of the π-type phase shifter, the first T-type phase shifter, the second T-type phase shifter, or a combination thereof.

In the embodiments mentioned above, the hybrid STPS circuitry may implement a 135° phase shift range with 45° phase resolution. For example, the hybrid STPD circuitry may utilize the π-type phase shifter to shift the phase of the input signal by 45°. Moreover, the hybrid STPD circuitry may utilize a combination of the π-type phase shifter, the first T-type phase shifter, and/or the second T-type phase shifter to shift the phase of the input signal by +45° and +90°. Alternative or additional phase shifter circuits with different phase shift values are also envisaged based on the circuitry and circuit blocks described herein.

If not compensated for, in some cases, different phase shifters may shift the phase of input signals having a single frequency by one or more phase shift values (e.g., −45°, +45°, +90°, among other values) with different phase drifts. For example, a first phase shifter may shift a phase of an input signal having a first frequency with a first phase shift and a first phase drift and a second phase shifter may shift the input signal having the first frequency with a second phase shift (or the first phase shift) and a second phase drift. Moreover, if not compensated for, the different phase shifters may shift a phase of the input signals having different frequencies across a frequency range by a phase shift value with different phase drifts. For example, the first phase shifter may shift a phase of input signals having a higher frequency with an increased phase drifts and the second phase shifter may shift the phase of the input signal having the higher frequency with even more increased phase drifts.

The hybrid STPS circuitry may include the π-type phase shifters and the T-type phase shifters to provide more stable output signals over a wide frequency range (e.g., greater than 30 gigahertz (GHz), greater than 36 GHz, between 40 GHz and 75 GHz, and so on). The hybrid STPS circuitry may provide the output signals based on shifting the phase of the input signal having different frequencies across the wide frequency range by different phase shifts with relatively similar phase drifts. Accordingly, the hybrid STPS circuitry described herein may have a reduced phase error during operation across a wide frequency range. In some cases, the phase shifters may also include one or more inductors. In some embodiments, stacking at least two inductors of the hybrid STPS circuitry may also reduce a circuit area for shifting the phase of the input signal by the desired phase shifts across the frequency range.

FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive signals between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer (e.g., in the form of a MacBook®, MacBook® Pro, MacBook Air®, iMac®, Mac® mini, or Mac Pro® available from Apple Inc. of Cupertino, California), a portable electronic or handheld electronic device such as a wireless electronic device or smartphone (e.g., in the form of a model of an iPhone® available from Apple Inc. of Cupertino, California), a tablet (e.g., in the form of a model of an iPad® available from Apple Inc. of Cupertino, California), a wearable electronic device (e.g., in the form of an Apple Watch® by Apple Inc. of Cupertino, California), and other similar devices. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with a memory 14 and a nonvolatile storage 16 to perform various algorithms. Such programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewntable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector provided by Apple Inc. of Cupertino, California, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, long term evolution (LTE®) cellular network, long term evolution license assisted access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

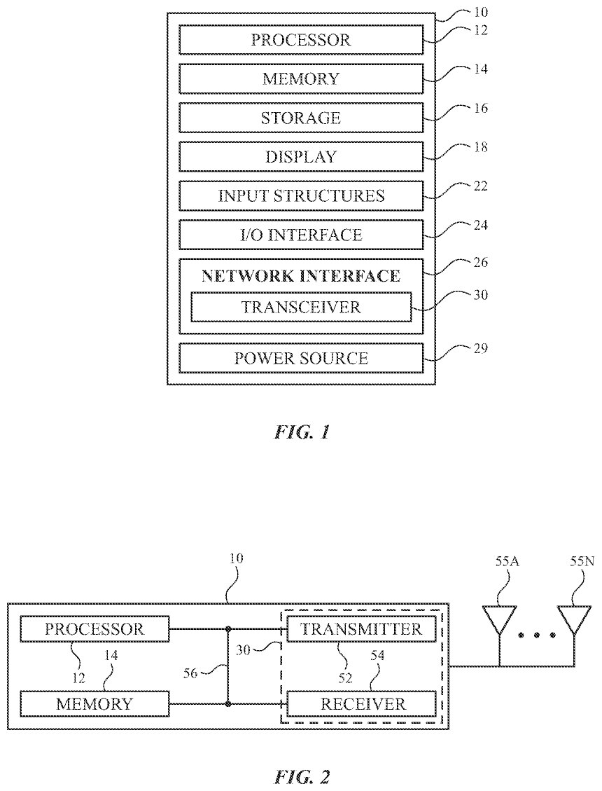

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (e.g., an array of antennas 55). The antennas 55 are illustrated as antennas 55A-55N and may be collectively referred to as an antenna 55. The antennas 55 may be communicatively coupled directly or indirectly (e.g., through or via another component, a communication bus, a network) to one another to transmit and/or receive signals between one another.

The electronic device 10 may include the transmitter 52 and/or the receiver 54 that respectively enable transmission and reception of signals between the electronic device 10 and an external device via, for example, a network (e.g., including base stations or access points) or a direct connection. As illustrated, the transmitter 52 and the receiver 54 may be combined into the transceiver 30. The electronic device 10 may also have antennas 55A-55N electrically coupled to the transceiver 30. The antennas 55A-55N may be configured in an omnidirectional or directional configuration, in a single-beam, dual-beam, or multi-beam arrangement, and so on. Each antenna 55 may be associated with one or more beams and various configurations. In some embodiments, multiple antennas of the antennas 55A-55N of an antenna group or module may be communicatively coupled to a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

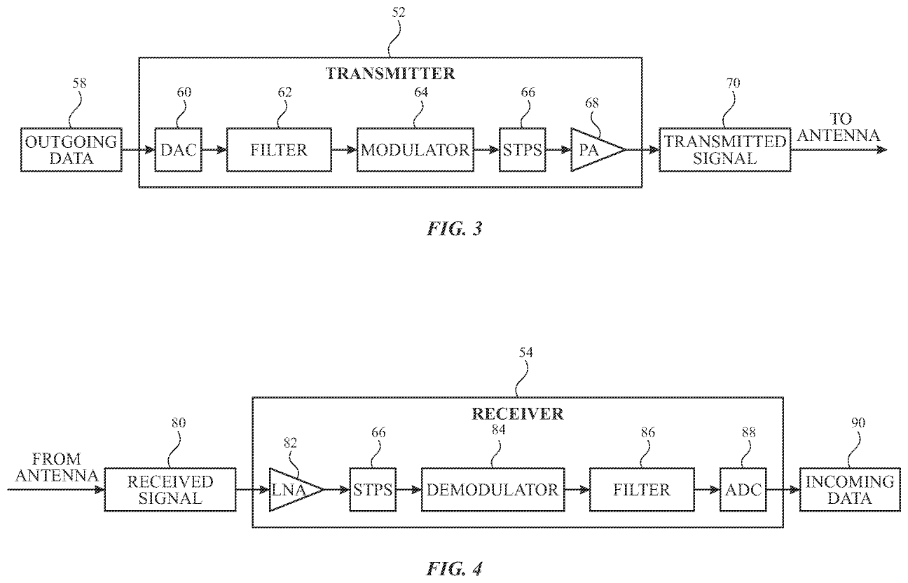

FIG. 3 is a schematic diagram of the transmitter 52 (e.g., transmit circuitry), according to embodiments of the present disclosure. As illustrated, the transmitter 52 may receive outgoing data 58 in the form of a digital signal to be transmitted via the antennas 55. A digital-to-analog converter (DAC) 60 of the transmitter 52 may convert the digital signal to an analog signal, a filter 62 (e.g., filter circuitry and/or software) may remove undesirable noise from the analog signal (e.g., a phase shifted analog signal), and a modulator 64 may combine the converted analog signal with a carrier signal to generate a radio wave. The filter 62 may include any suitable filter or filters to remove the undesirable noise from the amplified signal, such as a bandpass filter, a bandstop filter, a low pass filter, a high pass filter, and/or a decimation filter.

In some cases, a hybrid STPS circuitry 66 may shift a phase of the analog signal (e.g., a phase shifted modulated signal). A power amplifier (PA) 68 receives the modulated signal from the hybrid STPS circuitry 66. The power amplifier 68 may amplify the modulated signal to a suitable level to drive transmission of the signal via the antennas 55. In this manner, the power amplifier 68 may generate transmitted signal 70 to be transmitted via the antennas 55.

The transmitter 52 may be referred to as part of a radio frequency front end (RFFE), and more specifically, a transmit front end (TXFE) of the electronic device 10. Additionally, the transmitter 52 may include any suitable additional components not shown, or may not include certain of the illustrated components, such that the transmitter 52 may transmit the outgoing data 58 via the antennas 55. For example, the transmitter 52 may include a mixer and/or a digital up converter. As another example, the transmitter 52 may not include the filter 62 if the power amplifier 68 outputs the amplified signal in or approximately in a desired frequency range (such that filtering of the amplified signal may be unnecessary).

FIG. 4 is a schematic diagram of the receiver 54 (e.g., receive circuitry), according to embodiments of the present disclosure. As illustrated, the receiver 54 may receive received signal 80 from the antennas 55 in the form of an analog signal. A low noise amplifier (LNA) 82 may amplify the received analog signal to a suitable level for the receiver 54 to process. In some cases, the hybrid STPS circuitry 66 may shift a phase of the received analog signal. A demodulator 84 may remove a radio frequency carrier and/or extract a demodulated signal (e.g., an envelope) from the received analog signal (e.g., a phase shifted analog signal) for processing.

A filter 86 (e.g., filter circuitry and/or software) may remove undesired noise from the received signal, such as cross-channel interference. The filter 86 may also remove additional signals received by the antennas 55 that are at frequencies other than the desired signal. The filter 86 may include any suitable filter or filters to remove the undesired noise or signals from the received signal, such as a bandpass filter, a bandstop filter, a low pass filter, a high pass filter, and/or a decimation filter.

An analog-to-digital converter (ADC) 88 may receive the analog signal and convert the signal to a digital signal of incoming data 90 to be further processed by the electronic device 10. The receiver 54 may be referred to as part of the RFFE, and more specifically, a receiver front end (RXFE) of the electronic device 10. Moreover, it should be appreciated that the electronic device 10 may include multiple transmitters 52 and/or receivers 54 described above each coupled to one or more of the antennas 55 of the array of antennas 55. For example, the electronic device 10 may include a multi-channel circuit where each channel may include a number of the transmitters 52 and/or receivers 54 described above coupled to one or of the antennas 55. Additionally, the receiver 54 may include any suitable additional components not shown, or may not include certain of the illustrated components, such that the receiver 54 may receive the received signal 80 via the antennas 55. For example, the receiver 54 may include a mixer and/or a digital down converter.

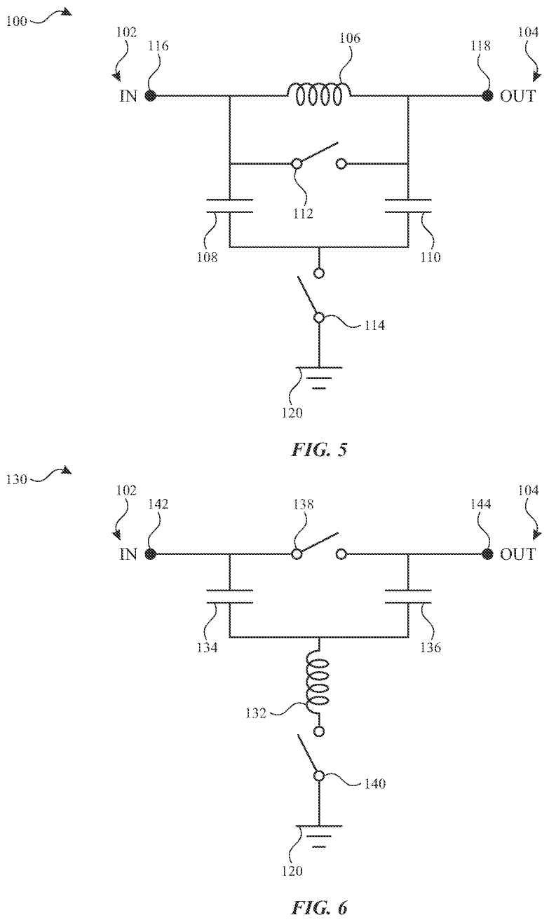

FIG. 5 is a circuit diagram of a low-pass π-type phase shifter 100 for shifting a phase of input signals 102. For example, the π-type phase shifter 100 may provide output signals 104 by shifting the phase of the input signals 102 by −45°. In some embodiments, the DAC 60 or the LNA 82 of the transceiver 30 discussed above may provide the input signals 102. Alternatively or additionally, other circuitry may provide the input signals 102. The π-type phase shifter 100 may include an inductor 106, a first capacitor 108, a second capacitor 110, a first switch 112, and a second switch 114.

The inductor 106 and the first switch 112 may be coupled in parallel to an input port 116 and an output port 118. Moreover, the first capacitor 108 may be coupled to the input port 116 and to a ground connection 120 (e.g., a 0 Volts (V) or near 0 V port, a virtual ground port, among other things) via the second switch 114. Furthermore, the second capacitor 110 may be coupled to the output port 118 and the ground connection 120 via the second switch 114. As such, closing the first switch 112 and opening the second switch 114 may bypass (e.g., short) the π-type phase shifter 100 including the inductor 106, the first capacitor 108, and the second capacitor 110.

In some cases, the first switch 112 may be closed and the second switch 114 may be open when the π-type phase shifter 100 is bypassed. To connect the π-type phase shifter 100 to the input port 116 and the output port 118, the processor 12, or any other viable controller circuitry, may provide control signals to open the first switch 112 and close the second switch 114. For example, the processor 12 may use information stored on the memory 14 to provide the control signals. As such, the first capacitor 108 may couple to the input port 116, the inductor 106, and the ground connection 120 and the second capacitor 110 may couple to the output port 118, the inductor 106, and the ground connection 120. That is, the first capacitor 108, the second capacitor 110, and the inductor 106 may form the π-type phase shifter 100 between the input port 116 and the output port 118. Accordingly, when connected to the input port 116 and the output port 118, the π-type phase shifter 100 may shift a phase of the input signals 102 by a phase shift value (e.g., −45°, among other shift values) based on capacitance values of the first capacitor 108 and the second capacitor 110 and an inductance value of the inductor 106.

FIG. 6 is a circuit diagram of a high-pass T-type phase shifter 130 for shifting a phase of the input signals 102. In different embodiments, the T-type phase shifter 130 may provide the output signals 104 by shifting the phase of the input signals 102 by +45°. For example, the DAC 60, the LNA 82, or any other viable circuitry may provide the input signals 102. The π-type phase shifter 100 may include an inductor 132, a first capacitor 134, a second capacitor 136, a first switch 138, and a second switch 140.

The first switch 138 may be coupled to an input port 142 and an output port 144. As such, closing the first switch 138 may bypass (e.g., short) the T-type phase shifter 130. The first capacitor 134 may be coupled to the input port 142 and the inductor 132. Moreover, the second capacitor 136 may be coupled to the output port 144 and the inductor 132. Furthermore, the second switch 140 may be coupled to the inductor 132 and the ground connection 120.

In some cases, the first switch 138 may be closed and the second switch 140 may be open when the T-type phase shifter 130 is bypassed. To connect the T-type phase shifter 130 to the input port 142 and the output port 144, the processor 12, or any other viable controller circuitry, may provide control signals to open the first switch 138 and close the second switch 140. For example, the processor 12 may use information stored on the memory 14 to provide the control signals. As such, the first capacitor 134, the second capacitor 136, and the inductor 132 may form the T-type phase shifter 130 between the input port 142 and the output port 144. Accordingly, when connected to the input port 116 and the output port 118, the T-type phase shifter 130 may shift a phase of the input signals 102 by a phase shift value (e.g., +45°, among other phase shift values) based on capacitance values of the first capacitor 134 and the second capacitor 136 and an inductance value of the inductor 132.

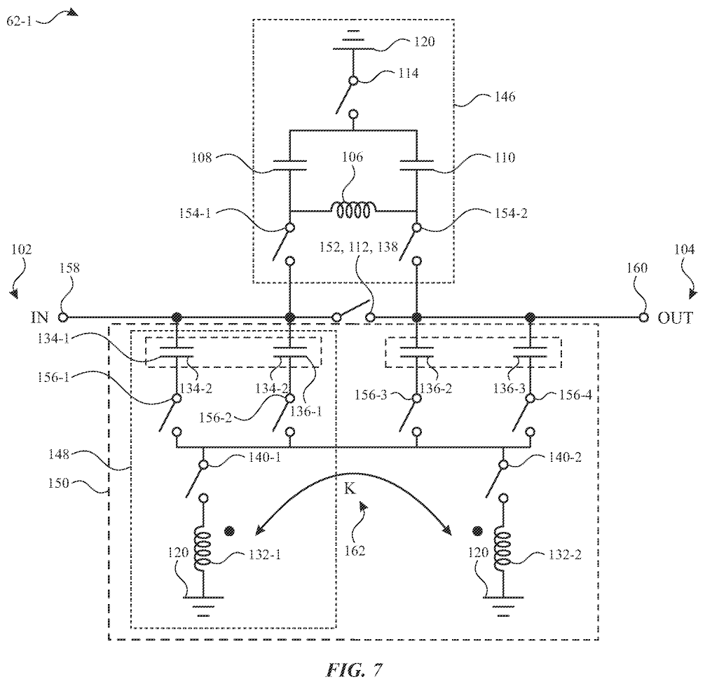

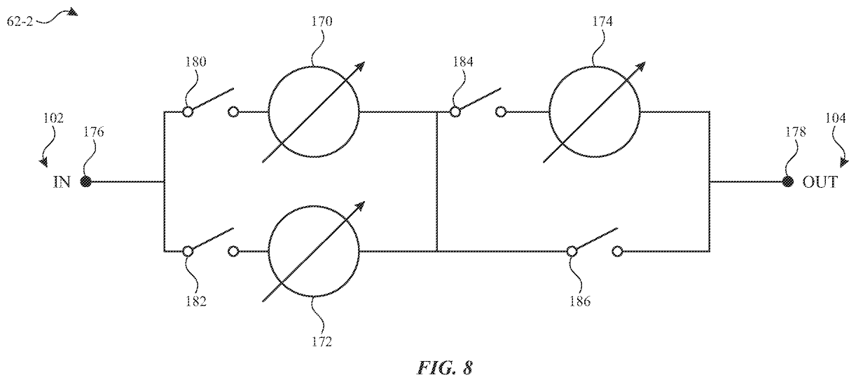

FIG. 7 is a circuit diagram of a first hybrid STPS circuitry 66-1 (e.g., phase shifting circuitry) mentioned above. In the depicted embodiment, the hybrid STPS circuitry 66-1 may include a first phase shifter 146, a second phase shifter 148, and a third phase shifter 150. In some embodiments, the first phase shifter 146 may include the π-type phase shifter 100 discussed above. The first phase shifter 146 may provide the output signals 104 by shifting the phase of the input signals 102 by a first phase shift value (e.g., by −45°) when activated. In the depicted embodiment, the first capacitor 108 may couple to a first terminal of the inductor 106 and the second capacitor 110 may couple to a second terminal of the inductor 106.

Moreover, the second phase shifter 148 and the third phase shifter 150 may each include the T-type phase shifter 130 with different capacitance and/or inductance values. For example, the second phase shifter 148 may provide the output signals 104 by shifting the phase of the input signals 102 by a second phase shift value (e.g., +45°) when activated. Moreover, the third phase shifter 150 may provide the output signals 104 by shifting the phase of the input signals 102 by a third phase shift value (e.g., +90°) when activated. In the depicted embodiment, the second phase shifter 148 and the third phase shifter 150 may share circuit components. In particular, the third phase shifter 150 may include the second phase shifter 148, as will be appreciated.

The hybrid STPS circuitry 66-1 may also include a first switch (e.g., a first set of switches) 152, second switches (e.g., a second set of switches) 154, and third switches (e.g., a third set of switches) 156. The first switch 152 may couple to an input port 158 and an output port 160 of the hybrid STPS circuitry 66-1. For example, in the depicted embodiment, the first switch 152 may correspond to the first switch 112 of the π-type phase shifter 100 and the first switch 138 of the T-type phase shifter 130 discussed above with respect to FIGS. 5 and 6. The first switch 152 may close when the second switches 154 and the third switches 156 are open to bypass (e.g., short, deactivate) the hybrid STPS circuitry 66-1. In some cases, the processor 12 may provide control signals to close the first switch 152 and open the second switches 154 and the third switch 156 to bypass the hybrid STPS circuitry 66-1 and/or cause providing the output signals 104 without a phase shift.

In the depicted embodiment, the second switches 154 may include second switches 154-1 and 154-2 for activating the first phase shifter 146. The second switches 154-1 and 154-2 may couple to the input port 158, the output port 160, and the first phase shifter 146. The first switch 152 and the second switches 154 may close to activate the first phase shifter 146. For example, the processor 12 may provide the control signals to close the first switch 152 and the second switches 154 to cause providing the output signals 104 with the first phase shift value (e.g., by −45°).

The third switches 156 may include third switches 156-1 and 156-2 for activating the second phase shifter 148 and may include third switches 156-1, 156-2, 156-3, and 156-4 for activating the third phase shifter 150. The third switches 156-1 and 156-2 may couple to the capacitors 134-1 and 136-1 and the inductor 132-1 of the second phase shifter 148 and the third phase shifter 150. Moreover, the third switches 156-3 and 156-4 may couple to the capacitors 136-2 and 136-3 and the inductor 132-2 of the third phase shifter 150. The first switch 152 and the third switches 156-1 and 156-2 may close to activate the second phase shifter 148. Moreover, the first switch 152 and the third switches 156-1, 156-2, 156-3, and 156-4 may close to activate the third phase shifter 150. For example, the processor 12 may provide the control signals or close the first switch 152 and the third switches 156-1 and 156-2 to cause providing the output signals 104 with the second phase shift value (e.g., by +45°) or close the first switch 152 and the third switches 156-1, 156-2, 156-3, and 156-4 to cause providing the output signals 104 with the third phase shift value (e.g., by +90°). Moreover, the second switch 140-1 may couple to a first terminal of the inductor 132-1 and the capacitors 134-1 and 136-1. Similarly, the second switch 140-2 may couple to a first terminal of the inductor 132-2 and the capacitors 136-2 and 136-3. A second terminal of the inductors 132-1 and 132-2 may be coupled to the ground connection 120.

When the third phase shifter 150 is activated, the capacitors 134-1 and 136-1 may couple in parallel and the capacitor 134-2 may couple in parallel to the capacitors 134-2 and 136-2. As such, when the third phase shifter 150 is activated, the capacitors 134-1 and 136-1 may form a first capacitor with a first capacitance value and the capacitors 136-2 and 136-3 may form a second capacitor with a second capacitance value. Moreover, the inductors 132-1 and 132-2 may be disposed in proximity of each other (e.g., in a stacked position) in the hybrid STPS circuitry 66-1. As such, the inductors 132-1 and 132-2 may inductively couple to each other based on a coupling factor 162 (K) (e.g., 0.1, 0.2, 0.3, 0.4, and so on) when the third phase shifter 150 is activated.

It should be appreciated that in different embodiments, the coupling factor 162 may be different based on a position of the inductors 132-1 and 132-2 in the hybrid STPS circuitry 66-1. Moreover, in some embodiments, the third phase shifter 150 may shift the phase of the input signals 102 by the third phase shift value (e.g., by +90°) higher than the second phase shift value (e.g., by +45°). In specific cases associated with such embodiments, if not compensated for, the inductors 132-1 and/or 132-2 (e.g., analog inductors) may have an increased size compared to the inductors 106. In such cases, if not compensated for, the inductors 132-1 and/or 132-2 may increase a size (e.g., footprint) of the hybrid STPS circuitry 66-1. In the depicted embodiment, a size of the hybrid STPS circuitry 66-1 may be reduced based on a reduced size of the inductors 132-1 and/or 132-2. The reduced size may be based on the disposition of the inductors 132-1 and 132-2 in proximity of each other in the hybrid STPS circuitry 66-1 resulting in the coupling factor 162 when the third phase shifter 150 is activated.

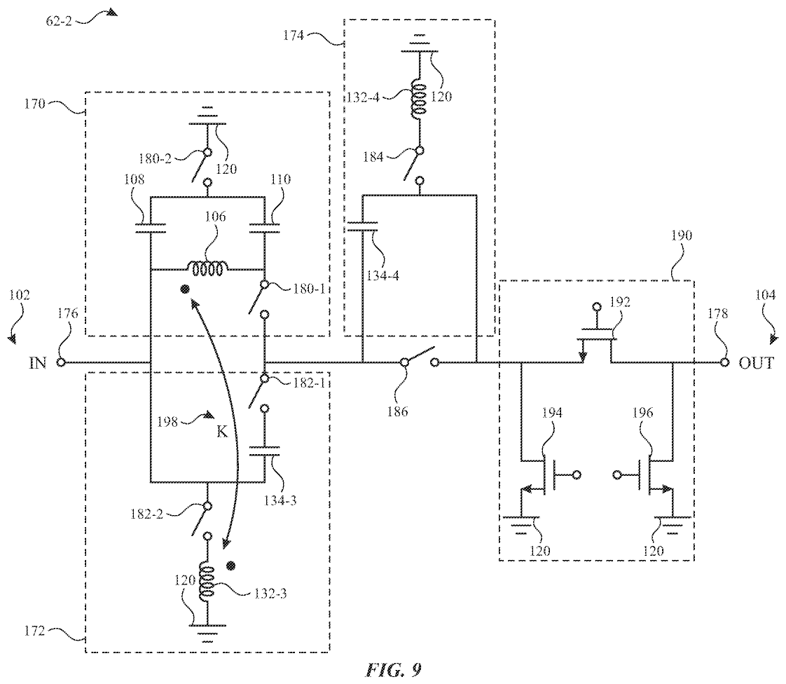

FIG. 8 is a circuit diagram of a second hybrid STPS circuitry 66-2 (e.g., phase shifting circuitry). In particular, the hybrid STPS circuitry 66-2 may include a first phase shifter 170, a second phase shifter 172, a third phase shifter 174, an input port 176, and an output port 178. The first phase shifter 170 may include the π-type phase shifter 100 described above with respect to FIG. 5. For example, a first terminal of the inductor 106 may be coupled to the capacitor 108 and an input terminal of the first phase shifter 170, and a second terminal of the inductor 106 may be coupled to the capacitor 110 and the first switch 180-1. The second phase shifter 172 and the third phase shifter 174 may each include the T-type phase shifter 130 described above with respect to FIG. 6. For example, a first terminal of the inductor 132-3 may couple to the second switch 182-2 and a second terminal of the inductor 132-3 may couple to the ground connection 120. Moreover, a first terminal of the inductor 132-4 may couple to the third switch 184 and a second terminal of the inductor 132-4 may couple to the ground connection 120.

For example, the first phase shifter 170 may shift the phase of the input signals 102 by a first phase shift value when activated. Moreover, when activated, the second phase shifter 172 and the third phase shifter 174 may each shift the phase of the input signals 102 by a second phase shift value and a third phase shift value respectively. By the way of example, the first phase shifter 170 may shift the phase of the input signals 102 by 45°, the second phase shifter 172 and the third phase shifter 174 may each shift the phase of the input signals 102 by +45° when activated. It should be appreciated that alternative or additional phase shift values are also envisaged for the first phase shifter 170, the second phase shifter 172, and the third phase shifter 174.

The hybrid STPS circuitry 66-2 may also include first switches 180, second switches 182, a third switch 184, and a fourth switch 186 to activate and deactivate the first phase shifter 170, the second phase shifter 172, and the third phase shifter 174. The switches 182, 184, 186, and 188 may couple (e.g., or activate) the first phase shifter 170, the second phase shifter 172, and/or the third phase shifter 174 in isolate or coupled in series during operation. For example, the processor 12 may provide the control signals to open and close the switches 182, 184, 186, and 188.

As shown in Table 1 below, the first switches 180 and the third switch 184 may close to activate the first phase shifter 170 and the third phase shifter 174 to provide the output signals 104 with no phase change (e.g., a 0° phase state). In particular, the first phase shifter 170 may shift the phase of the input signals by −45° and the third phase shifter 174 may shift the phase of the input signals by +45° to shift the phase of the input signals by 0° in aggregate. For example, the first phase shifter 170 (e.g., the π-type phase shifter 100) and the third phase shifter 174 (e.g., the T-type phase shifter 130) may shift the phase of the input signals in series to improve the phase response (e.g., a phase drift) for the 0° phase state.

Referring back to Table 1 below, the first switches 180 and the fourth switch 186 may close to activate the first phase shifter 170 for shifting the phase of the input signals 102 by −45°. Moreover, the second switches 182 and the third switch 184 may close to activate the second phase shifter 172 and the third phase shifter 174 for shifting the phase of the input signals 102 by +90°. For example, the second phase shifter 172 (e.g., the T-type phase shifter 130) and the third phase shifter 174 (e.g., the T-type phase shifter 130) may couple to shift the phase of the input signals in series to improve the phase response (e.g., a phase drift) when providing the output signals 104 with +90° phase shift.

Moreover, the second switches 182 and the fourth switch 186 may close to activate the second phase shifter 172 for shifting the phase of the input signals 102 by +45°. As such, based at least in part on using the π-type phase shifter 100 and the T-type phase shifter 130, the hybrid STPS circuitry 66-2 may enable the phase shifts to change with frequency, reducing phase error over a frequency band, thus making this embodiment suitable for wideband phase response. As illustrated, the embodiments may operate, for example, in the frequency band, as defined by the Institute of Electrical and Electronics Engineers (IEEE). The frequency band may include a band of frequencies in a microwave portion of an electromagnetic spectrum ranging from greater than 30 GHz, greater than 36 GHz, between 40 GHz and 75 GHz, and so on. Alternatively or additionally, the embodiments described above may operate at any viable range of frequencies.

TABLE 1

| | First Switches | Second Switches | Third Switch | Fourth Switch |
|---|---|---|---|---|
| 0° | Close | Open | Close | Open |
| −45° | Close | Open | Open | Close |
| +90° | Open | Close | Close | Open |
| +45° | Open | Close | Open | Close |

FIG. 9 is a circuit diagram of the hybrid STPS circuitry 66-2 discussed above. In the depicted embodiment, the hybrid STPS circuitry 66-2 may include the first phase shifter 170, the second phase shifter 172, the third phase shifter 174, and an attenuator 190. Although specific circuitry is described in the depicted embodiment of FIG. 9, it should be appreciated that the hybrid STPS circuitry 66-2 may include alternative or additional circuit components in alternative or additional embodiments.

As discussed above, the first phase shifter 170 may include the π-type phase shifter 100. In particular, the first phase shifter 170 may include the first capacitor 108, the second capacitor 110, and the inductor 106. Moreover, the first phase shifter 170 may include the first switches 180-1 and 180-2. In some cases, the processor 12 may provide one or more control signals to open and close the first switches 180-1 and 180-2. Closing the first switches 180-1 and 180-2 may activate the first phase shifter 170 and opening the first switches 180-1 and 180-2 may deactivate the first phase shifter 170.

The second phase shifter 172 may include the T-type phase shifter 130 with a reduced number of capacitors. In the depicted embodiment, the second phase shifter 172 may include the first capacitor 134-3 and the inductor 132-3. The second phase shifter 172 may also include second switches 182-1 and 182-2. In some cases, the processor 12 may provide one or more control signals to open and close the second switches 182-1 and 182-2. Closing the second switches 182-1 and 182-2 may activate the second phase shifter 172 and opening the first switches 180-1 and 180-2 may deactivate the first phase shifter 170.

Similarly, the third phase shifter 174 may include the T-type phase shifter 130 with a reduced number of capacitors. In the depicted embodiment, the third phase shifter 174 may include the first capacitor 134-4 and the inductor 132-4. Moreover, the third phase shifter 174 may include the third switch 184. In some cases, the processor 12 may provide one or more control signals to open and close the third switch 184. Closing the third switch 184 may activate the third phase shifter 174 and opening the third switch 184 may deactivate the third phase shifter 174.

The attenuator 190 may include transistors 192, 194, and 196. The transistors 192, 194, and 196 may each receive one or more signals from the processor 12 or any other viable circuitry. The attenuator 190 may provide a constant gain when providing the output signals 104. For example, the attenuator 190 may provide the output signals 104 with a relatively constant gain at various phase modes (e.g., 0° phase shift, −45° phase shift, +45° phase shift, +90° phase shift, and so on) and/or various frequencies.

As mentioned above, the second phase shifter 172 and the third phase shifter 174 may each include the T-type phase shifter 130 with a reduced number of capacitors. In particular, the T-type phase shifter 130 discussed above with respect to FIG. 6 may include a second capacitor 136 not shown in the circuit diagrams of the second phase shifter 172 and the third phase shifter 174. The second phase shifter 172 and the third phase shifter 174 depicted in FIG. 9 may include the T-type phase shifters 130 with the reduced number of capacitors (e.g., not include the second capacitor 136) based on coupling the phase shifters (e.g., in series) for shifting (e.g., positively shifting, negatively shifting, or both) the phase of the input signals. As such, for example, an aggregate capacitance, parasitic capacitance, and/or mutual capacitance, among other things, may reduce a number of components (e.g., capacitors) used in the hybrid STPS circuitry 66-2. As such, in some cases, a size (e.g., footprint) of the hybrid STPS circuitry 66-2 may reduce based on activating the first phase shifter 170, the second phase shifter 172, and the third phase shifter 174.

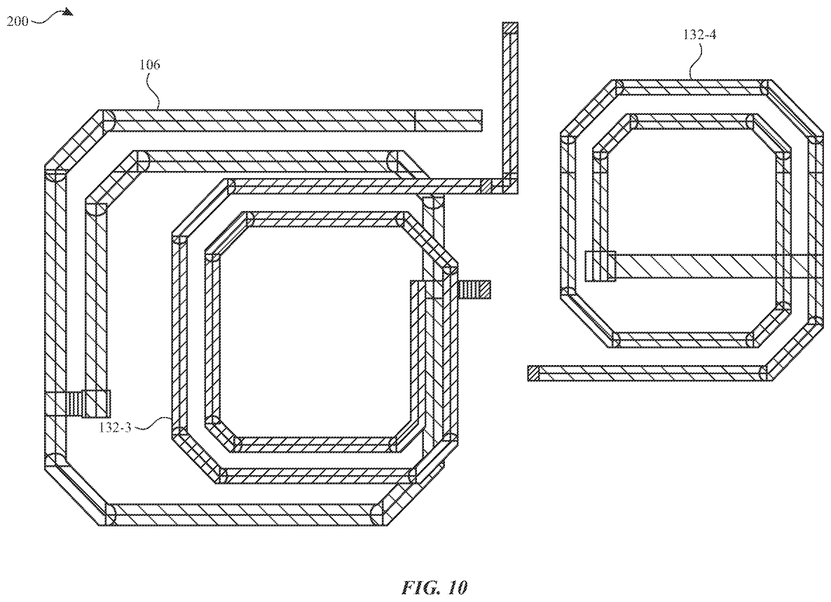

Moreover, the inductors 106 and 132-3 may be inductively coupled based on a coupling factor 198 (K) during operation of the first phase shifter 170 and the second phase shifter 172. For example, the inductors 106 and 132-3 may be disposed stacked together, disposed on each other, and/or positioned in proximity of each other such that the inductors 106 and 132-3 may be inductively coupled when the first phase shifter 170 and the second phase shifter 172 are activated. Accordingly, a size of the inductor 106 and/or the inductor 132-3 may be reduced. For example, the conductive coupling of the inductors 106 and 132-3 may reduce an area of the inductor 106 and/or inductor 132-3 for operation within a desired frequency range (e.g., greater than 30 GHz, greater than 36 GHz, between 40 GHz and 75 GHz, and so on). An example embodiment of the inductors 106, 132-3, and 132-4 is shown in FIG. 10 and described below.

FIG. 10 is a layout 200 of the inductors 106, 132-3, and 132-4 of the hybrid STPS circuitry 66-2 discussed above. As mentioned above, the inductive coupling of the inductors 106 and 132-3 during operation may reduce an area of the inductor 106 and/or the inductor 132-3 for operation within a desired frequency range. Moreover, in some cases, the size of one or more analog components of the hybrid STPS circuitry 66-2 may correspond to a size of the hybrid STPS circuitry 66-2. As such, in the depicted embodiment, a size of the hybrid STPS circuitry 66-2 may be reduced based on a reduced area of the inductors 106, 132-3, and/or 132-4. For example, in specific cases, an area occupied by the hybrid STPS circuitry 66-2 including the inductors 106, 132-3, and 132-4 for operation within a desired frequency range (e.g., 37-48-2 GHz) may be reduced (e.g., reduced to 0.011 millimeters squared (mm²)) as compared to other embodiments of the hybrid STPS circuitry 66 including inductors.

The embodiments of the hybrid STPS circuitry 66 described above may include the π-type phase shifter 100 and the T-type phase shifter 130 to provide more stable output signals over a wide frequency range (e.g., greater than 30 GHz, greater than 36 GHz, between 40 GHz and 75 GHz, and so on). The hybrid STPS circuitry 66 may provide the output signals based on shifting the phase of the input signal having different frequencies across the wide frequency range by different phase shifts with relatively similar phase drifts. Accordingly, the hybrid STPS circuitry 66 described herein may have a reduced phase error during operation across a wide frequency range. In some cases, the phase shifters discussed above may also include one or more capacitors and/or inductors. In some embodiments, a layout or circuitry of such phase shifters may be shared such that a total number of capacitors may be reduced. Therefore, the phase shifter circuitry described above may reduce a circuit area of the hybrid STPS circuitry 66. Moreover, stacking at least two inductors of the hybrid STPS circuitry may also reduce a circuit area for shifting the phase of the input signal by the desired phase shifts across the frequency range.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. Phase shifting circuitry comprising:
a first phase shifter comprising a first inductor, a first capacitor coupled to a first terminal of the first inductor, and a second capacitor coupled to a second terminal of the first inductor, the first capacitor and the second capacitor coupled to a first switch, the first switch coupled to a ground connection; and
a second phase shifter comprising
a third phase shifter comprising a second inductor, a third capacitor coupled to a second switch, and a fourth capacitor coupled to the second switch, the second switch coupled to a third terminal of the second inductor, a fourth terminal of the second inductor coupled to the ground connection,
a third inductor,
a fifth capacitor coupled to a third switch, and
a sixth capacitor coupled to the third switch, the third switch coupled to a fifth terminal of the third inductor, and a sixth terminal of the third inductor coupled to the ground connection.

2. The phase shifting circuitry of claim 1, wherein the third inductor is configured to inductively couple to the second inductor when the second phase shifter is activated.

3. The phase shifting circuitry of claim 1, comprising an input port and an output port, wherein the first phase shifter comprises a first set of switches, the first set of switches configured to open and close to decouple and couple the first phase shifter from and to the input port and the output port, the first set of switches configured to close to activate the first phase shifter.

4. The phase shifting circuitry of claim 1, wherein the third phase shifter comprises a second set of switches, the second set of switches configured to open and close to decouple and couple the third capacitor from and to the second inductor.

5. The phase shifting circuitry of claim 4, wherein the second set of switches are configured to close to activate the third phase shifter.

6. The phase shifting circuitry of claim 4, wherein the second phase shifter comprises a third set of switches, the third set of switches configured to open and close to decouple and couple the fifth capacitor and the sixth capacitor from and to the third inductor.

7. The phase shifting circuitry of claim 6, wherein the second set of switches and the third set of switches close to activate the second phase shifter.

8. An electronic device comprising:
one or more antennas; and
a hybrid switched-type phase shifter coupled to the one or more antennas, the hybrid switched-type phase shifter comprising
a π-type phase shifter configured to shift a phase of an input signal by a first phase shift value, the input signal being transmitted by the one or more antennas or received by the one or more antennas,
a first T-type phase shifter configured to shift the phase of the input signal by a second phase shift value, and
a second T-type phase shifter configured to shift the phase of the input signal by a third phase shift value.

9. The electronic device of claim 8, comprising a processor coupled to the hybrid switched-type phase shifter, the processor configured to activate and deactivate the π-type phase shifter, the first T-type phase shifter, and the second T-type phase shifter.

10. The electronic device of claim 9, wherein the processor activates the π-type phase shifter to shift the phase of the input signal by the first phase shift value, activates the first T-type phase shifter to shift the phase of the input signal by the second phase shift value, or activates the second T-type phase shifter to shift the phase of the input signal by the third phase shift value.

11. The electronic device of claim 9, wherein the processor activates the π-type phase shifter and the second T-type phase shifter to shift the phase of the input signal by an aggregate of the first phase shift value and the third phase shift value.

12. The electronic device of claim 9, wherein the processor activates the first T-type phase shifter and the second T-type phase shifter to shift the phase of the input signal by an aggregate of the second phase shift value and the third phase shift value.

13. The electronic device of claim 8, wherein the first T-type phase shifter comprises a first inductor, the second T-type phase shifter comprises a second inductor, and the first inductor and the second inductor are configured to inductively couple upon activation of the first T-type phase shifter and the second T-type phase shifter.

14. The electronic device of claim 8, wherein the π-type phase shifter comprises a first inductor, the first T-type phase shifter comprises a second inductor, and the first inductor and the second inductor are configured to inductively couple upon activation of the π-type phase shifter and the first T-type phase shifter.

15. A hybrid switched-type phase shifter comprising:
a π-type phase shifter coupled to an input port via a first set of switches;
a first T-type phase shifter coupled to the input port via a second set of switches; and
a second T-type phase shifter coupled to an output port, the second T-type phase shifter coupled in series to the π-type phase shifter and the first T-type phase shifter.

16. The hybrid switched-type phase shifter of claim 15, comprising a switch coupled to the π-type phase shifter, the first T-type phase shifter, the second T-type phase shifter, and the output port, the switch configured to close to bypass the second T-type phase shifter.

17. The hybrid switched-type phase shifter of claim 15, wherein
the π-type phase shifter comprises
a first inductor,
a first terminal of the first inductor coupled to the input port,
a first capacitor coupled to the input port, the first terminal of the first inductor, and a first switch of the first set of switches, the first switch coupled to a ground connection, and
a second capacitor coupled to a second terminal of the first inductor, the first capacitor, the first switch, and a second switch of the first set of switches, and
the first T-type phase shifter comprises
a second inductor coupled to a third switch of the second set of switches, the third switch coupled to the input port, and
a third capacitor coupled to the third switch and a fourth switch of the second set of switches.

18. The hybrid switched-type phase shifter of claim 17, wherein the first inductor is inductively coupled to the second inductor when the π-type phase shifter is activated, the first T-type phase shifter is activated, or both.

19. The hybrid switched-type phase shifter of claim 15, wherein the second T-type phase shifter comprises
a third inductor coupled to a ground connection and a fifth switch, and
a fourth capacitor coupled to the fifth switch, an output terminal of the π-type phase shifter, and an output terminal of the T-type phase shifter.

20. The hybrid switched-type phase shifter of claim 15, comprising a plurality of switches configured to activate the π-type phase shifter, the first T-type phase shifter, the second T-type phase shifter, or any combination thereof, to shift a phase of input signals.
